(19) United States
(12) Patent Application Publication
(10) Pub. No.: US 2012/0140572 A1
(43) Pub. Date: Jun. 7, 2012

(54) SEMICONDUCTOR MEMORY DEVICE AND METHOD OF OPERATING THE SAME

(76) Inventors: Jae Yun KIM, Jeollanam-do (KR); Young Soo PARK, Seoul (KR); Eui Sang YOON, Seoul (KR)

(21) Appl. No.: 13/181,800

(22) Filed: Jul. 13, 2011

(30) Foreign Application Priority Data
Dec. 3, 2010 (KR) 10-2010-0122917

(51) Int. Cl. G11C 7/10

(52) U.S. Cl. 365/189.05

(57) ABSTRACT

A semiconductor memory device includes a switching element coupled between a power supply line and an output terminal of a power supply circuit for supplying a power supply voltage, wherein the switching element is configured to be turned on in response to a standby signal, a page buffer including a plurality of latch circuits, wherein a voltage input terminal of at least one of the latch circuits is coupled to the output terminal of the power supply circuit and a voltage input terminal of at least another one of the latch circuits is coupled to the power supply line, and a control logic circuit configured to generate the standby signal according to an operation mode of the semiconductor memory device.

### CROSS-REFERENCE TO RELATED APPLICATION

Priority to Korean patent application number 10-2010-0122917 filed on Dec. 3, 2010, the entire disclosure of which is incorporated by reference herein, is claimed.

### BACKGROUND

Exemplary embodiments relate to a semiconductor memory device and a method of operating the same.

An erase operation for erasing data stored in the memory cells of a nonvolatile semiconductor memory device that is electrically erased and programmed and a program operation for storing data in the memory cells are performed using Fowler-Nordheim (F-N) tunneling and a hot electron injection method.

The semiconductor memory device may include a memory cell array, a row decoder, and a page buffer. The memory cell array may include a plurality of word lines elongated in rows, a plurality of bit lines elongated in columns, and a plurality of cell strings corresponding to the respective bit lines.

A page buffer may be coupled to a bit line. The page buffer may include latch circuits for temporarily storing data to be programmed into selected memory cells or for storing data read from the memory cells.

In order to further increase the degree of integration, a multi-level cell (MLC) capable of programming one memory cell with several threshold voltage levels may be used. In using the MLC, the number of latch circuits included in the page buffer may increase accordingly.

Here, each latch circuit may include two inverters. The latch circuit is a volatile storage device capable of retaining data only during the time when a power source is supplied.

According to exemplary embodiments, it is desirable that some latch circuits included in the page buffer of the semiconductor memory device retain data even in a standby mode. To this end, it is desirable that a power source be continuously supplied to some latch circuits in order to maintain data even in the standby mode.

However, in previous power supply schemes, the same power source supplied to some latch circuits that are to retain data even in a standby mode is supplied to other latch circuits included in the page buffer of the semiconductor memory device that are not to retain data in the standby mode. In other words, the power source supplied to retain data stored in some latch circuits is also supplied to the remaining latch circuits. Such a power supply scheme results in additional power consumption.

### BRIEF SUMMARY

Exemplary embodiments relate to a semiconductor memory device capable of supplying different power supply voltages to a latch circuit required to retain data in the standby mode and to a latch circuit not required to retain data in the standby mode, and a method of operating the same.

A semiconductor memory device according to an aspect of the present disclosure includes a switching element coupled between a power supply line and an output terminal of a power supply circuit for supplying a power supply voltage, wherein the switching element is configured to be turned on in response to a standby signal, a page buffer including a plurality of latch circuits, wherein a voltage input terminal of at least one of the latch circuits is coupled to the output terminal of the power supply circuit and a voltage input terminal of at least another one of the latch circuits is coupled to the power supply line, and a control logic circuit configured to generate the standby signal according to an operation mode of the semiconductor memory device.

A page buffer circuit of the semiconductor memory device according to another aspect of the present disclosure includes a plurality of latch circuits, wherein a voltage input terminal of at least one of the latch circuits is arranged to continuously receive a power supply voltage irrespective of an operation mode of the semiconductor memory device and a voltage input terminal of at least another one of the latch circuits is arranged to discontinuously receive the power supply voltage depending on the operation mode.

A method of operating the semiconductor memory device that comprises memory cells and a page buffer including latch circuits for communicating data with the memory cells according to yet another aspect of the present disclosure includes providing a power supply voltage to a first voltage input terminal and a second voltage input terminal, and supplying the power supply voltage to at least one of the latch circuits through the first voltage input terminal and supplying the power supply voltage to at least another one of the latch circuits through the second voltage input terminal, and discontinuing the supply of the power supply voltage to the second voltage input terminal in a standby mode of the semiconductor memory device.

### BRIEF DESCRIPTION OF THE DRAWINGS

FIG. 1 is a block diagram of a semiconductor memory device;

FIG. 2 is a circuit diagram of a page buffer of FIG. 1;

FIG. 3A illustrates a first latch of FIG. 2;

FIG. 3B illustrates a second latch of FIG. 2;

FIG. 4 is a diagram illustrating a power supply circuit of FIG. 1; and

FIG. 5 is a flowchart illustrating the operation of the page buffer with respect to the supply of a power source according to an exemplary embodiment of this disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

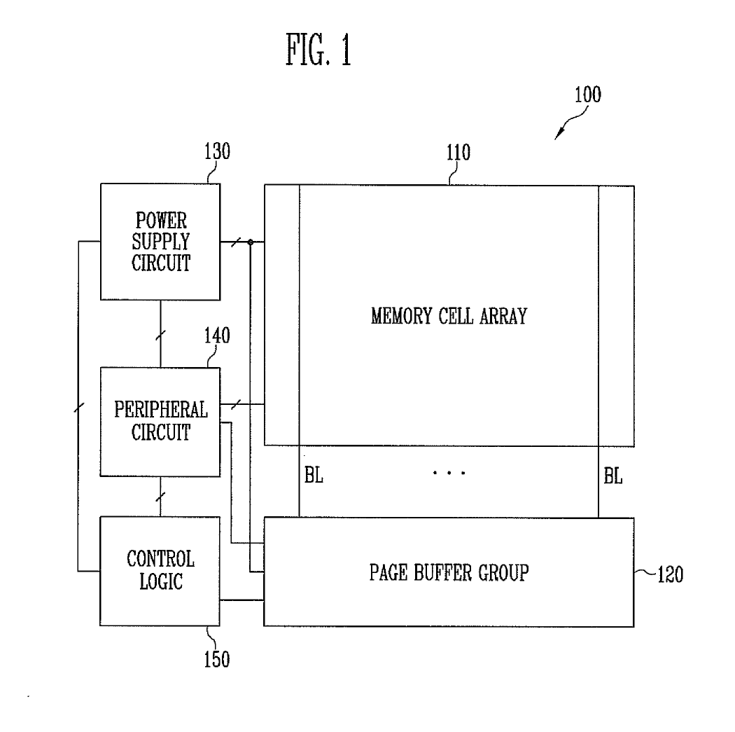

FIG. 1 is a block diagram of a semiconductor memory device.

Referring to FIG. 1, semiconductor memory device 100 includes a memory cell array 110, a page buffer group 120, a power supply circuit 130, a peripheral circuit 140, and a control logic 150.

The memory cell array 110 includes a plurality of memory cells. The memory cells are coupled to word lines and bit lines BL.

The page buffer group 120 includes page buffers coupled to the respective bit lines. The page buffers include latch circuits for storing data to be programmed into memory cells selected by a word line and a bit line or for reading data stored in selected memory cells and storing the read data.

The power supply circuit 130 generates operating voltages (for example, a program voltage Vpgm, a read voltage Vread, a verification voltage Vverify, an erase voltage Verase, and a power source Vcc) for the operations of the page buffer group 120 and the peripheral circuit 140.

The peripheral circuit 140 includes circuits for a program operation of storing data into the memory cells and a data read operation of reading data stored in the memory cells.

The control logic 150 generates control signals for controlling the operations of the page buffer group 120, the power supply circuit 130, and the peripheral circuit 140.

An exemplary page buffer of the page buffer group 120 is described below.

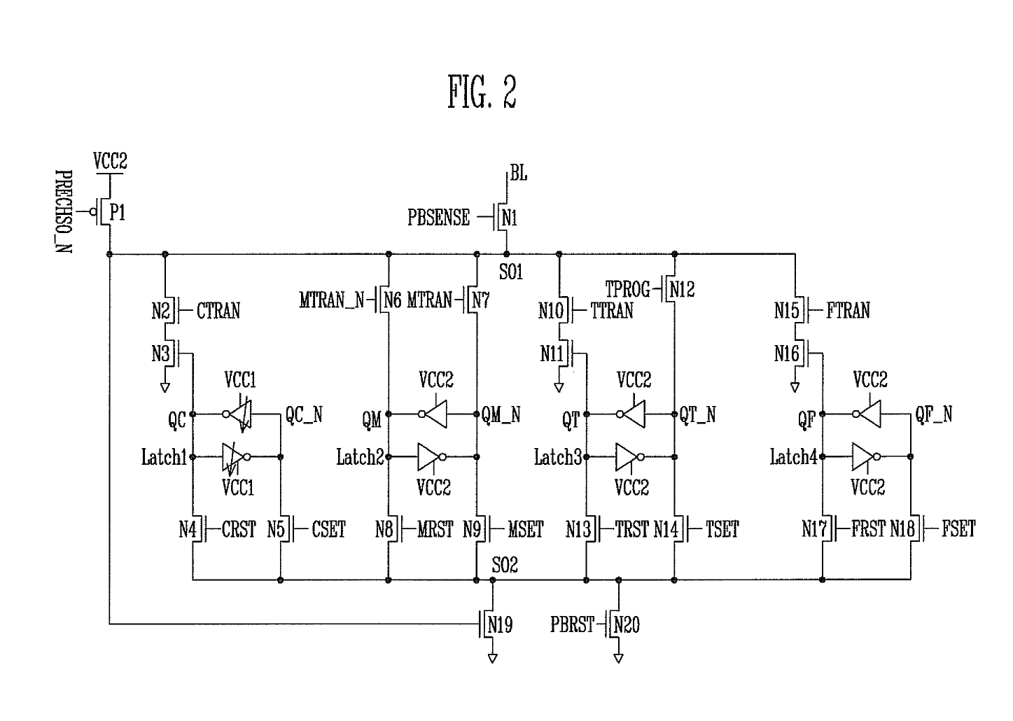

FIG. 2 is a circuit diagram of the page buffer of FIG. 1.

Referring to FIG. 2, the page buffer includes 1^{st} to 20^{th} NMOS transistors N1 to N20, a first PMOS transistor P1, and first to fourth latches Latch1 to Latch4.

The first NMOS transistor N1 is coupled between the bit line BL and a first sense node SO1. A sense signal PBSENSE is supplied to the gate of the first NMOS transistor N1.

The first NMOS transistor N1 transfers voltage of the bit line BL to the first sense node 501.

The first PMOS transistor P1 is coupled between a second power supply voltage VCC2 and the first sense node SO1. A precharge signal PRECHSO_N is supplied to the gate of the first PMOS transistor P1.

The first PMOS transistor P1 precharges the first sense node SO1 to the second power supply voltage VCC2 in response to the precharge signal PRECHSO_N.

The second and third NMOS transistors N2 and N3 are coupled in series between the first sense node SO1 and a ground node. A first transmission signal CTRAN is supplied to the gate of the second NMOS transistor N2. The gate of the third NMOS transistor N3 is coupled to a node QC.

The first latch Latch1 is coupled between the node QC and a node QC_N and is configured to include two inverters. The inverters constituting the first latch Latch1 are operated in response to a first power supply voltage VCC1. Details of the inverters of the first latch Latch1 will be described later.

The fourth NMOS transistor N4 is coupled between the node QC and a second sense node 502. The fifth NMOS transistor N5 is coupled between the node QC_N and the second sense node 502.

A first reset signal CRST is supplied to the gate of the fourth NMOS transistor N4. A first set signal CSET is supplied to the gate of the fifth NMOS transistor N5.

The sixth NMOS transistor N6 is coupled between the first sense node SO1 and a node QM. The seventh NMOS transistor N7 is coupled between the first sense node SO1 and a node QM_N.

An inverse signal MTRAN_N of a second transmission signal MTRAN is supplied to the gate of the sixth NMOS transistor N6. The second transmission signal MTRAN is supplied to the gate of the seventh NMOS transistor N7.

The second latch Latch2 includes two inverters coupled between the node QM and the node QM_N. The two inverters constituting the second latch Latch2 are operated in response to a second power supply voltage VCC2. Details of the two inverters of the second latch Latch2 will be described later.

The eighth NMOS transistor NS is coupled between the node QM and the second sense node SO2. The ninth NMOS transistor N9 is coupled between the node QM_N and the second sense node 502.

A second reset signal MRST is supplied to the gate of the eighth NMOS transistor N8. A second set signal MSET is supplied to the gate of the ninth NMOS transistor N9.

The tenth and eleventh NMOS transistors N10 and N11 are coupled in series between the first sense node SO1 and the ground node. A third transmission signal TTRAN is supplied to the gate of the tenth NMOS transistor N10. The gate of the eleventh NMOS transistor N11 is coupled to a node QT.

The twelfth NMOS transistor N12 is coupled between the first sense node SO1 and a node QT_N. A program control signal TPROG is supplied to the gate of the twelfth NMOS transistor N12.

The third latch Latch3 includes two inverters coupled between the node QT and the node QT_N. The two inverters of the third latch Latch3 like the inverters in the second latch Latch2 are operated in response to the second power supply voltage VCC2.

The thirteenth NMOS transistor N13 is coupled between the node QT and the second sense node 502. The fourteenth NMOS transistor N14 is coupled between the node QT_N and the second sense node 502.

A third reset signal TRST is supplied to the gate of the thirteenth NMOS transistor N13. A third set signal TSET is supplied to the gate of the fourteenth NMOS transistor N14.

The fifteenth and sixteenth NMOS transistors N15 and N16 are coupled in series between the first sense node SO1 and the ground node. A fourth transmission signal FTRAN is supplied to the gate of the fifteenth NMOS transistor N15. The gate of the sixteenth NMOS transistor N16 is coupled to a node QF.

The fourth latch Latch4 includes two inverters coupled between the node QF and a node QF_N. The two inverters of the fourth latch Latch4 like the inverters in the second and the third latches Latch2 and Latch3 are operated in response to the second power supply voltage VCC2.

The seventeenth NMOS transistor N17 is coupled between the node QF and the second sense node SO2. The eighteenth NMOS transistor N18 is coupled between the node QF_N and the second sense node SO2.

A fourth reset signal FRST is supplied to the gate of the seventeenth NMOS transistor N17. A fourth set signal FSET is supplied to the gate of the eighteenth NMOS transistor N18.

The nineteenth NMOS transistor N19 is coupled between the second sense node SO2 and the ground node. The gate of the nineteenth NMOS transistor N19 is coupled to the first sense node S01.

The twentieth NMOS transistor N20 is coupled between the second sense node SO2 and the ground node. A page buffer reset signal PBRST is supplied to the gate of the twentieth NMOS transistor N20.

In the page buffer as described above, the first power supply voltage VCC1 is supplied to the first latch Latch1, and the second power supply voltage VCC2 is supplied to the second to fourth latches Latch1 to Latch4.

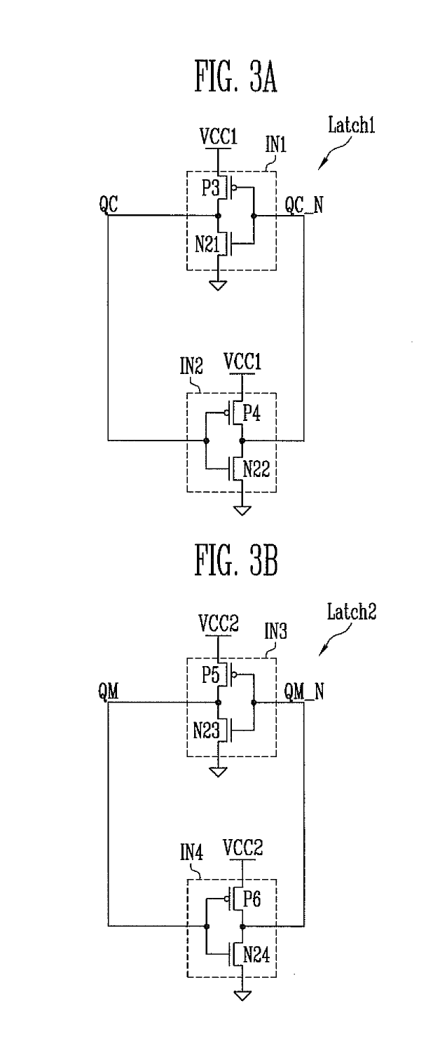

FIG. 3A illustrates the first latch of FIG. 2, and FIG. 3B illustrates the second latch of FIG. 2.

Referring to FIG. 3A, the first latch Latch1 includes first and second inverters IN1 and IN. The first inverter IN1 includes a third PMOS transistor P3 and a 21^{st} NMOS transistor N21. The second inverter IN2 includes a fourth PMOS transistor P4 and a 22^{nd} NMOS transistor N22.

The third PMOS transistor P3 and the 21^{st} NMOS transistor N21 are coupled in series between the first power supply voltage VCC1 and the ground node. The gates of the third PMOS transistor P3 and the 21^{st} NMOS transistor N21 are commonly coupled to the node QC_N. A node of the third PMOS transistor P3 and the 21^{st} NMOS transistor N21 is coupled to the node QC.

The fourth PMOS transistor P4 and the 22^{nd} NMOS transistor N22 are coupled in series between the first power supply voltage VCC1 and the ground node. The gates of the fourth PMOS transistor P4 and the 22^{nd} NMOS transistor N22 are commonly coupled to the node QC. An intervening node of the fourth PMOS transistor P4 and the 22^{nd} NMOS transistor N22 is coupled to the node QC_N.

As previously described, the first power supply voltage VCC1 is supplied to the first and second inverters IN1 and IN2.

Details of the second latch Latch2 are shown in FIG. 3B.

Referring to FIG. 3B, the second latch Latch2 includes third and fourth inverters IN3 and IN4.

The third inverter IN3 includes a fifth PMOS transistor P5 and a 23^{rd} NMOS transistor N23. The fourth inverter IN4 includes a sixth PMOS transistor P6 and a 24^{th} NMOS transistor N24.

The fifth PMOS transistor P5 and the 23^{rd} NMOS transistor N23 are coupled in series between the second power supply voltage VCC2 and the ground node. The gates of the fifth PMOS transistor P5 and the 23^{rd} NMOS transistor N23 are commonly coupled to the node QM_N.

An intervening node of the fifth PMOS transistor P5 and the 23^{rd} NMOS transistor N23 is coupled to the node QM.

The sixth PMOS transistor P6 and the 24^{th} NMOS transistor N24 are coupled in series between the second power supply voltage VCC2 and the ground node. The gates of the sixth PMOS transistor P6 and the 24^{th} NMOS transistor N24 are commonly coupled to the node QM. An intervening node of the sixth PMOS transistor P6 and the 24^{th} NMOS transistor N24 is coupled to the node QM_N.

Each of the third and fourth latches Latch3 and Latch4 has the same construction as the second latch Latch2, where they are supplied with the second power supply voltage VCC2. Thus, a detailed description thereof is omitted.

As shown in FIGS. 3A and 3B, the first power supply voltage VCC1 is supplied to the first latch Latch1, and the second power supply voltage VCC2 for precharging the first sense node SO1 of the page buffer is supplied to the second to fourth latches Latch 2 to Latch4.

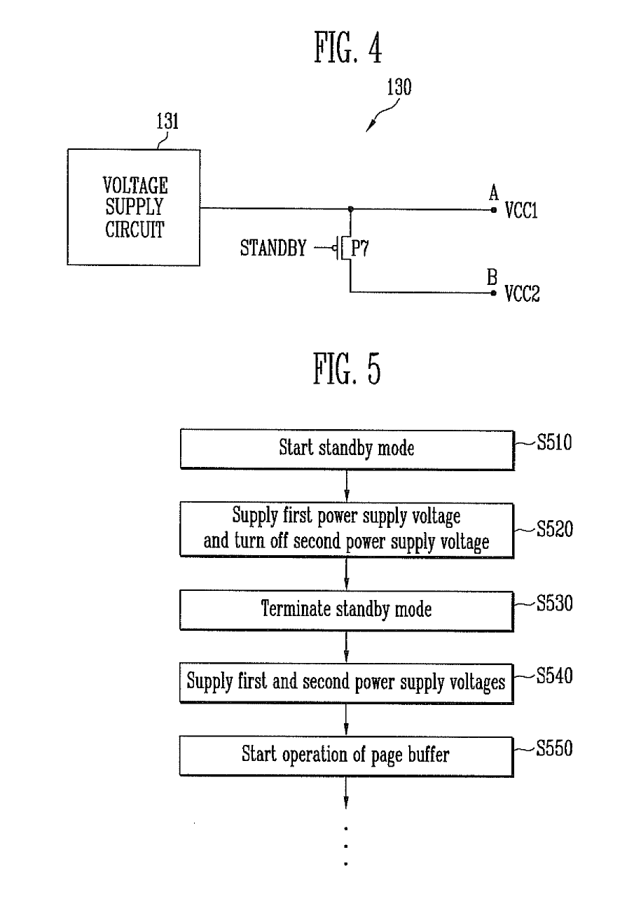

The first and second power supply voltages VCC1 and VCC2 are supplied through a first voltage input terminal A and a second voltage input terminal B, respectively. The power source generated by the power supply circuit 130 is supplied to the first and the second voltage input terminals A and B (shown in FIG. 4).

In an exemplary embodiment of this disclosure, the first power supply voltage VCC1 continues to be supplied to the semiconductor memory device 100 during the time for which the power source is supplied. The second power supply voltage VCC2 is supplied in the active mode but not in the standby mode.

To this end, the power supply circuit 130 includes different voltage supply lines for supplying the first and the second power supply voltages VCC1 and VCC2 as described below.

FIG. 4 is a diagram showing a relevant part of the power supply circuit of FIG. 1.

FIG. 4 is a diagram showing the first and the second voltage input terminals A and B for supplying the first and the second power supply voltages VCC1 and VCC2, respectively, in the power supply circuit 130 of FIG. 1.

The power supply circuit 130 includes a voltage supply circuit 131. The power supply voltage outputted from the voltage supply circuit 131 is output to voltage supply terminals for the first power supply voltage VCC1 and the second power supply voltage VCC2.

Here, the first power supply voltage VCC1 is outputted without change, and the second power supply voltage VCC2 is supplied through a seventh PMOS transistor P7, where there may be, if any, a slight voltage decrease through the seventh PMOS transistor P7.

The seventh PMOS transistor P7 is coupled between the output terminal of the voltage supply circuit 131 and the output terminal of the second power supply voltage VCC2. A standby signal STANDBY is supplied to the gate of the seventh PMOS transistor P7.

According to an example, the standby signal STANDBY is generated by the control logic 150. When the standby signal STANDBY is in a high level, the memory circuit is operated in the standby mode.

In the standby mode, the second power supply voltage VCC2 is not supplied because the seventh PMOS transistor P7 is turned off.

Accordingly, the first power supply voltage VCC1 is supplied to the page buffer irrespective of an operation mode of the page buffer, but the second power supply voltage VCC2 is not supplied to the page buffer in the standby mode.

Thus, data stored in the first latch Latch1 remains intact in the standby mode, and data stored in the second to fourth latches Latch2 to Latch4 are lost in the standby mode.

FIG. 5 is a flowchart illustrating the operation of the page buffer with respect to the supply of a power source according to an exemplary embodiment of this disclosure.

Referring to FIG. 5, when the power source starts to be supplied to the semiconductor memory device 100 and the standby mode is entered at step S510, the control logic 150 generates the standby signal STANDBY of a high level.

In response to the standby signal, the seventh PMOS transistor P7 is turned off. Accordingly, the supply of the second power supply voltage VCC2 is blocked at step S520.

Next, when the standby mode is terminated and another operation mode is entered at step S530, the control logic 150 changes the standby signal STANDBY from a high level to a low level.

When the standby signal STANDBY of a low level is generated, the seventh PMOS transistor P7 is turned on. In response to the low standby signal STANDBY, both the first power supply voltage VCC1 and the second power supply voltage VCC2 are supplied at step S540.

At this time, the second to fourth latches Latch2 to Latch4 to which the second power supply voltage VCC2 is supplied are to be reset through, for example, operations of the FIG. 2 circuit. This is because data stored in the second to fourth latches Latch 2 to Latch4 are unknown since the previously stored data have been lost in the standby mode. Here, according to an example, the first latch Latch1 is not to be reset when the second power supply voltage VCC2 is supplied after a standby mode.

The second to fourth latches Latch 2 to Latch4 may be reset immediately after the second power supply voltage VCC2 is supplied in response to the change from the standby mode to the active mode or immediately before an operation to be performed on the page buffer (for example, the second to fourth latches Latch2 to Latch4).

During the time that the first and the second power supply voltages VCC1 and VCC2 are supplied, the operation of the page buffer according to a desired operation mode is started at step S550. The operation of the page buffer is controlled by control signals from the control logic 150.

According to an exemplary embodiment, a power supply voltage may be prevented from being unnecessarily provided in the standby mode.

According to an exemplary embodiment, different power supply voltages may be supplied to a latch circuit intended to retain data in the standby mode and a latch circuit designed not to retain data in the standby mode. Here, power consumption may be reduced by blocking a power supply of latch circuits designed not to retain data in the standby mode.

What is claimed is:

1. A semiconductor memory device, comprising:
a switching element coupled between a power supply line and an output terminal of a power supply circuit for supplying a power supply voltage, wherein the switching element is configured to be turned on in response to a standby signal;
a page buffer including a plurality of latch circuits, wherein a voltage input terminal of at least one of the latch circuits is coupled to the output terminal of the power supply circuit and a voltage input terminal of at least another one of the latch circuits is coupled to the power supply line; and
a control logic circuit configured to generate the standby signal according to an operation mode of the semiconductor memory device.

2. The semiconductor memory device of claim 1, wherein:
each of the latch circuits comprises two inverters, and
the two inverters of the at least another one of the latch circuits are configured to lose stored data when the switching element is turned off.

3. The semiconductor memory device of claim 1, wherein the control logic circuit is configured to generate a control signal to initiate a reset operation for the at least another one of the latch circuits immediately after a termination of a standby mode of the semiconductor memory device.

4. The semiconductor memory device of claim 1, wherein the control logic circuit is configured to generate a control signal to initiate a reset operation for the at least another one of the latch circuits immediately before an operation is performed on the page buffer after a termination of a standby mode of the semiconductor memory device.

5. A page buffer circuit of a semiconductor memory device, the page buffer circuit comprising:
a plurality of latch circuits, wherein a voltage input terminal of at least one of the latch circuits is arranged to continuously receive a power supply voltage irrespective of an operation mode of the semiconductor memory device and a voltage input terminal of at least another one of the latch circuits is arranged to discontinuously receive the power supply voltage depending on the operation mode.

6. The page buffer circuit of claim 5, wherein the power supply voltage is supplied to the voltage input terminal of the at least another one of the latch circuits in an active mode but not in a standby mode.

7. The page buffer circuit of claim 5, wherein the at least another one of the latch circuits is configured to be reset immediately after a termination of a standby mode of the semiconductor memory device or immediately before an operation is to be performed on the at least another one of the latch circuits after the termination of the standby mode.

8. The page buffer circuit of claim 5, wherein the at least one of the latch circuits is configured to retain stored data in a standby mode of the semiconductor memory device and the at least another one of the latch circuits is configured to lose stored data in the standby mode.

9. The page buffer circuit of claim 8, wherein the at least one of the latch circuits is configured to not be reset after the standby mode and the at least another one of the latch circuits is configured to be reset after the standby mode.

10. A method of operating a semiconductor memory device that comprises memory cells and a page buffer including latch circuits for communicating data with the memory cells, the method comprising:
providing a power supply voltage to a first voltage input terminal and a second voltage input terminal; supplying the power supply voltage to at least one of the latch circuits through the first voltage input terminal and supplying the power supply voltage to at least another one of the latch circuits through the second voltage input terminal; and
discontinuing the supply of the power supply voltage to the second voltage input terminal in a standby mode of the semiconductor memory device.

11. The method of claim 10, wherein the power supply voltage is continuously supplied to the first power source input terminal irrespective of an operation mode of the semiconductor memory device.

12. The method of claim 10, wherein when the supply of the power supply voltage to the second voltage input terminal is discontinued, two inverters of the at least another one of the latch circuits lose stored data.

13. The method of claim 10, further comprising performing a reset operation for the at least another one of the latch circuits after a termination of the standby mode.

14. The method of claim 10, further comprising performing a reset operation for the at least another one of the latch circuits immediately before an operation is performed on the at least another one of the latch circuits after a termination of the standby mode.
